(19) United States
(12) Patent Application Publication
(10) Pub. No.: US 2002/0110204 A1
(43) Pub. Date: Aug. 15, 2002

(54) Radiofrequency signal receiver with control means for the channels to be controlled

(75) Inventors: Pierre-Andre Farine, Neuchatel (CH); Jean-Daniel Etienne, Les Geneveys-sur-Coffrane (CH); Ruud Riem-Vis, Neuchatel (CH); Elham Firouzi, Ligerz (CH)

Correspondence Address: SUGHRUE, MION, ZINN, MACPEAK & SEAS, PLLC, 2100 Pennsylvania Avenue, N.W., Washington, DC, 20037-3202, US

(73) Assignee: ASULAB S.A.

(21) Appl. No.: 10/000,037

(22) Filed: Dec. 4, 2001

(30) Foreign Application Priority Data
Dec. 18, 2000 (CH) 2471/00

(51) Int. Cl. H04L 27/06; H03D 1/00

(52) U.S. Cl. 375/343

(57) ABSTRACT

The radiofrequency signal receiver (1) includes means (3) for receiving and shaping radiofrequency signals into intermediate signals (IF), a correlation stage (7) which includes several correlation channels (7′) for receiving the intermediate signals (IF), microprocessor means (12) connected to said correlation stage for the transfer of control and/or data signals. The receiver also includes channel selection means, such as a priority decoder (13), connected to all the channels (7′) of the correlation stage (7) and to the microprocessor means (12). These selection means allow the channel with the highest priority among the operating channel or channels which have each transmitted an interruption signal for a data transfer from the selected channel to the microprocessor means (12), to be placed first in a virtual channel, in accordance with a defined order of priority for all the channels.

The present invention concerns a radiofrequency signal receiver including means for receiving and shaping said radiofrequency signals into intermediate signals, a correlation stage which includes several correlation channels for receiving the intermediate signals, microprocessor means connected to said correlation stage for the transfer of control and/or data signals.

Radiofrequency receivers, in particular of the GPS type, generally include several correlation channels connected to a main microprocessor. Usually, in a normal operating mode, the microprocessor is intended to take care of all the channel synchronising tasks for acquiring and tracking at least four visible satellites. Once certain channels are locked onto a respective satellite, demodulated GPS data is transmitted to the microprocessor for calculating the X, Y, Z position of the receiver, as well as the speed and/or time.

During all these satellite search and tracking procedures, the operating channels transmit interruption signals to the microprocessor to warn it of data which it can pick up. As soon as it receives interruption signals, the microprocessor has to scan through all the channels to find out from which channel the data to be picked up originates. This data may concern for example configuration parameters, GPS messages, the state of the pseudo-random PRN code, the frequency increment relating to the Doppler effect, pseudo-ranges, receiving means interruption modes, the state of integrator counters and other information.

The fact that the microprocessor has to scan through all the channels, in order to discover from which channels the interruption signals originate during these search and tracking operations, constitutes a significant waste of time which is a drawback. This waste of time leads, on the one hand, to the microprocessor providing the position, speed and/or time data only after a long period of operation, and on the other hand to the receiver consuming a large amount of energy. Energy consumption must of course be saved if one wishes to mount the GPS receiver in a portable device, such as a watch or a portable telephone, as the device in such case is powered by a battery or an accumulator of small size.

An object of the present invention consists in providing a radiofrequency signal receiver provided with means allowing a microprocessor quickly to access a channel which has transmitted an interruption signal for a data transfer, which overcomes the aforementioned drawbacks.

This object, in addition to others, is achieved by the radiofrequency signal receiver cited above, which is characterised in that it includes channel selection means connected to all the channels of the correlation stage and to the microprocessor means, said selection means allowing the channel with the highest priority among the operating channel or channels which have each transmitted an interruption signal for a data transfer from the selected channel to the microprocessor means, to be placed first in a virtual channel, in accordance with a defined order of priority for all the channels.

Owing to these selection means, such as a priority decoder, upon receiving an interruption signal, the microprocessor of the microprocessor means will be able to access directly one of the selected channels which has the highest priority without having to scan through all the channels. Direct access to the priority channel transmitting an interruption signal also permits a reduction in energy consumption. This provides an advantage in the event that the GPS receiver is mounted in a device using a battery or an accumulator of small size, such as a watch or a portable telephone.

In order to reach this situation, the microprocessor has to address the virtual channel. With this, the priority decoder will select, when there are interruptions to several channels, the channel which has the highest priority to present it first to the microprocessor. Depending upon the cause of interruption of the selected channel which is communicated to the microprocessor, the microprocessor means generates addresses for accessing the corresponding registers of the selected channel. Once the addressed register data of the selected channel have been read, a read confirmation is transmitted to the selected channel removing the channel interruption. After this, the next interruption to the same channel or another channel can be selected through the virtual channel while keeping the order of priority amongst the channels.

The use of the virtual channel of the priority decoder is essential during all the urgent synchronisation tasks for acquiring and tracking visible satellites by the correlation channels. In an initial phase, the microprocessor means have the time to transfer configuration parameters for each channel, which means that the use of the virtual channel is not necessary.

The objects, advantages and features of the radiofrequency signal receiver will appear more clearly in the following description of embodiments illustrated by the drawings, in which:

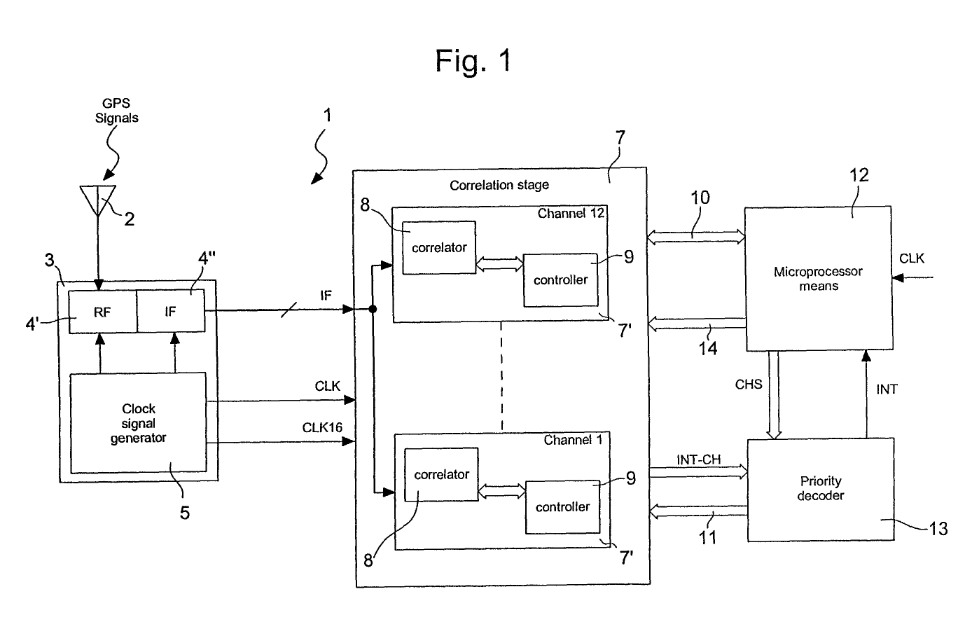

FIG. 1 shows schematically a radiofrequency signal receiver including a priority decoder according to the invention, and

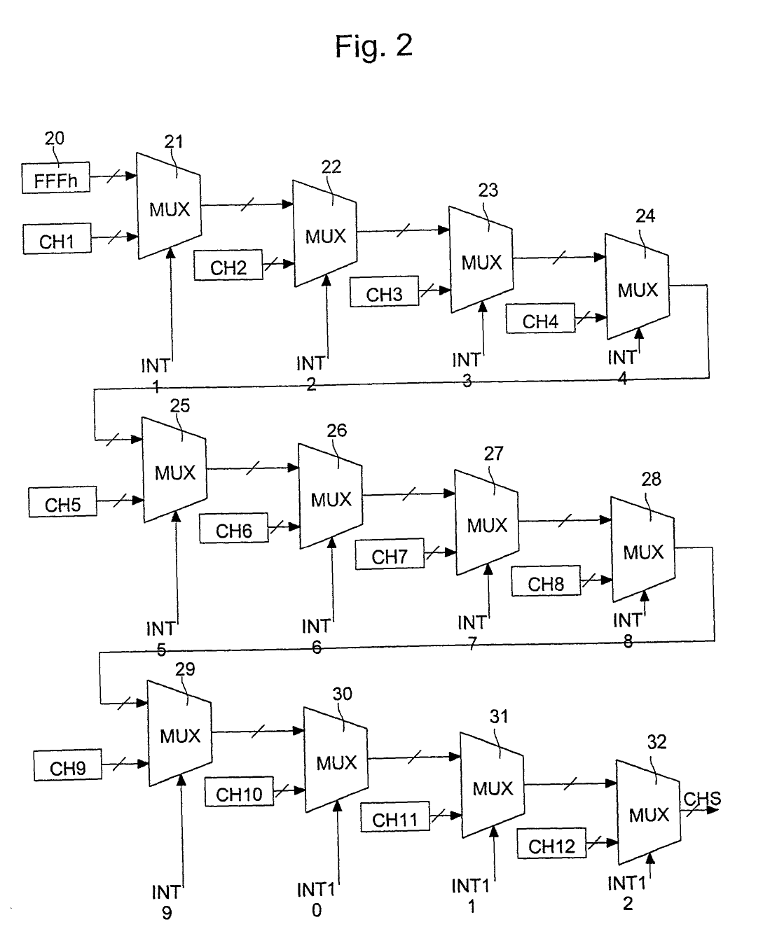

FIG. 2 shows schematically the electronic elements of the priority decoder according to the invention.

The following description will be made in relation to a GPS type radiofrequency signal receiver. Several parts of this receiver will not be explained in detail since they form part of the general knowledge of those skilled in the art in this technical field.

The GPS type radiofrequency signal receiver is shown schematically in FIG. 1. It is formed of an antenna 2 for receiving GPS radiofrequency signals from several satellites, means 3 for receiving and shaping the radiofrequency signals into intermediate signals IF, a correlation stage 7 with several correlation channels 7′ receiving intermediate signals IF for example at a frequency of the order of 400 kHz, microprocessor means 12 and means for selecting channels 7′ such as a priority decoder 13. The elements of priority decoder 13 will be explained with reference to FIG. 2.

Conventionally, in receiving means 3, a first electronic circuit 4′ first of all converts the radiofrequency signals of frequency 1,57542 GHz into a frequency of for example 179 MHz. A second electronic circuit IF 4″ effects a double conversion to bring the GPS signals first of all to a frequency of 4.76 MHz, then finally to a frequency of for example 400 kHz by sampling at 4.36 MHz. Intermediate complex signals IF sampled and quantified at a frequency of the order of 400 kHz are thus provided to channels 7′ of correlation stage 7.

Intermediate complex signals IF are formed of an in-phase signal and a quarter-phase signal represented in the Figure by a bold line intersected by an oblique bar defining 2 bits. However, in accordance with other embodiments which are not shown, intermediate signals IF could be provided over 4 bits or more, or include only an in-phase signal provided over 1 bit.

For the frequency conversion operations, a clock signal generator 5 forms part of the radiofrequency signal receiving and shaping means 3. This generator is provided for example with a quartz oscillator which is not shown, calibrated at a frequency of the order of 17.6 MHz. Two clock signals CLK and CLK16 are provided in particular to correlation stage 7 and to microprocessor means 12 to clock all the operations of these elements. The first clock frequency CLK can have a value 4.36 MHz, while the second clock frequency may be fixed at 16 times less, i.e. 272.5 kHz used for a large part of the correlation stage in order to save energy consumption.

Correlation stage 7 is formed of 12 correlation channels 7′ which each include a correlator 8 and a controller 9 intended to set into operation, via a dedicated material, a signal processing algorithm for acquiring and tracking a satellite detected by the channel.

Correlator 8 of each correlation channel 7′ includes a carrier mixer, a code mixer, integrator counters, code and carrier discriminators, code and carrier numerically controlled oscillators, a pseudo-random code generator, and a carrier sin/cos table. For the sake of simplification, not all of these elements have been shown in FIG. 1 since they form part of the general knowledge of those skilled in the art in this technical field. The reader may refer for further details to the teaching drawn from the book “Understanding GPS Principles and Applications” at chapter 5 by Philip Ward and by the editor Elliott D. Kaplan (Artech House Publishers, USA 1996) ISBN edition number 0-89006-793-7, and in particular to FIGS. 5.8 and 5.13 showing the aforecited elements in large lines.

The arrangement of controllers 9 in each channel has the advantage of avoiding having to make too many data transfers during these acquisition and tracking phases between all the operating channels and microprocessor means 12. If all the synchronisation tasks of all the channels were done in collaboration with a single microprocessor, the energy consumption of the receiver would become significant.

Since all these synchronisation tasks are advantageously performed by the combination of correlator 8 and controller 9 in each channel, it is not necessary to have a large sized microprocessor in microprocessor means 12. An 8-bit microprocessor can be sufficient to calculate the X, Y, Z position, speed and/or time. This microprocessor may for example be an 8-bit CoolRISC-816 microprocessor by EM Microelectronic-Marin SA, Switzerland.

Microprocessor means 12 also include memory means, as well as an address decoder, which are not shown in FIG. 1. The memory means include data relating to each satellite placed in orbit and pseudo-random code and carrier frequency parameter data for each satellite. In order to extract data from one or several registers of a selected channel, the address decoder sends address signals via a dedicated bus 14 to select the register or registers to be read.

In correlation stage 7 for each channel 7′, several data and/or configuration parameter input and output buffer registers are provided, but they are not shown to avoid overloading FIG. 1. The data placed in the registers concerns in particular the GPS messages, the state of the PRN code, the frequency increment relating to the Doppler effect, pseudo-ranges and other data. A data and/or parameter transfer bus 10 connects the microprocessor means to the registers of the respective channels. Via this bus 10, control signals from microprocessor means 12 can also be transmitted to correlation channels 7′ particularly in order to set them into operation.

It should be noted that these registers can accumulate data during the channel search and tracking procedures without necessarily being automatically transferred to microprocessor means 12. However, when at least one interruption signal has reached said microprocessor means, at least one register of a selected channel has to be read.

Thus, microprocessor means 12 transmit, via bus 10, parameters relating to the pseudo-random code to be searched and the carrier frequency of the intermediate signals, before the search and tracking procedures. These parameters are transmitted to shape all of channels 7′ individually prior to starting the actual search and tracking procedures.

In order to reach each channel, microprocessor means 12 controls a priority decoder which can be configured. In order to do this, they send a channel number determined by the CHS bus to priority decoder 13. Since the correlation stage has 12 channels, the channel number binary word includes 4 bits. Configured decoder 13 will thus send, via bus 11, selection signals for the channel desired by microprocessor means 12. For this preliminary transfer of configuration parameters, the microprocessor can take time to do it.

However, when the satellite search and tracking procedures are started for channels 7′, it is necessary to have quick access to all the data signalled and stored in the registers. In this case, microprocessor means 12 send the number of a virtual channel, selected to be number 15, to priority decoder 13. In this configuration of the priority decoder, the channel which has the highest identification number has priority with respect to the other channels of lower rank when there are several channel interruption signals which are sent by the INT-CH bus to priority decoder 13.

There must be at least one interruption in a channel for the decoder to signal it to microprocessor means 12 by sending it an interruption instruction INT. From this instant on, the channel which generated this interruption will be selected by priority decoder 13 in order to put it first.

A correlation stage state register stores the data concerning the causes of interruption. This data message is normally formed of 8 bits with 1 bit of GPS data, 3 bits of interruption causes and 4 bits of the number of the channel transmitting the interruption signal. Upon receiving the interruption instruction, the message stored in the state register is read by the microprocessor which will thus activate the address decoder so that it sends address signals to the selected channel via bus 14. The sent addresses will allow the microprocessor to read the data of certain registers of the selected channel as a function of the cause of interruption.

Once the data have been read by the microprocessor, the latter transmits in return into the same register which has been read, a read confirmation value. From this instant on, the interruption instruction is cancelled, and a new interruption instruction for the same channel or another channel can be sent.

By way of information, the table below shows the causes of interruption, stored in the channel registers, which may occur during the search and tracking procedures of the operating channels:

| Cause of interruption | Bit value |
|---|---|
| No interruptions | 000 |
| New GPS data available | 001 |
| Satellite search accomplished | 010 |
| Interruption started | 011 |
| New pseudo-range stored | 100 |
| Loss of bit synchronisation | 101 |
| Tracking mode started | 110 |
| Apparition of integrator output value | 111 |

It may happen that during the satellite search and tracking procedures by the correlation channels in operation, several interruption signals appear at the same time indicating to the microprocessor that certain data can be extracted from the channels which have transmitted these interruptions. In order to do this, priority decoder 13 configured with the virtual channel allows the channel which has the highest identification number among the channels transmitting interruption signals to be selected and placed first.

All the channel interruptions are processed by the microprocessor in the order in which such interruptions appear and as a function of the order of priority imposed on the channels. It may happen that several causes of interruption stored in one of the channels are processed one after the other before another channel takes priority.

The priority of a channel will be examined after processing of the preceding channel has finished. With this order imposed by the priority decoder, the microprocessor means can access directly the channel deliberately placed first in the virtual channel without having to scan through them all.

Correlation stage 7, microprocessor means 12 and priority decoder 13 may be made on a same semiconductor substrate, for example, made of silicon. A clock frequency divider of clock signal generator 5 could also form part of the correlation stage to generate clock signals or signals CLK and CLK16.

FIG. 2 shows the electronic elements of the priority decoder used to be able to place the priority channel first in a virtual channel during the occurrence of interruptions.

The priority decoder includes a number of multiplexers 21 to 32 placed one after the other wherein the output of one is connected to the input of the other in chronological order. This number of multiplexers corresponds to the number of channels of the correlation stage. The other input of each multiplexer 21 to 32 receives the identification number CH1 to CH12 of the corresponding channel. Each multiplexer is controlled by a specific interruption control signal INT1 to INT12 originating from the channel transmitting the interruption. In the configuration shown, the first multiplexer 21 is controlled by a control signal INT1 originating from the first channel, whereas the second multiplexer 22 is controlled by a control signal INT2 originating from the second channel, and so on to the last multiplexer 32 controlled by the interruption control signal INT12 originating from the twelfth channel.

The output of the last multiplexer 32 supplies the selection signals for the priority channel to be placed first as a function of interruption signals INT1 to INT12 provided that the microprocessor has sent the number of the virtual channel to the decoder. Normally, the microprocessor sends the virtual channel number, as soon as it receives an interruption instruction, since it is upon receiving this instruction that it has to place a priority channel transmitting the interruption first in the virtual channel.

Depending upon whether the interruption control signal INT1 to INT12 is in the high state or the low state, the output of each multiplexer controlled by this signal will supply either the channel identification number, or the output value of the preceding multiplexer. The first multiplexer 21 receives at an input 20 a binary value which may be formed of all the 1, which would define the number of the virtual channel if no interruption occurred. It may also happen that the number of a specific channel supplied by the microprocessor is introduced at this input for the selection of a particular channel.

In the present case, when the interruption control signal INT1 to INT12 is in the high or low state, i.e. 1 or 0, it is the output value of the preceding multiplexer which is entered in the following multiplexer, while if this signal is in the low or high state, it is the identification number of a channel of the corresponding multiplexer which is provided at output.

If, for example, two interruption control signals INT3 and INT6 are provided by the channels CH3 and CH6, multiplexer 23 will supply the identification number of the third channel which will pass through multiplexers 24 and 25 to reach the input of multiplexer 26. However, in multiplexer 26 controlled by interruption signal INT6, it is the identification number of the sixth channel which will be supplied in place of the identification number of the third channel. Since no other interruption instruction is provided to the other following multiplexers, the identification number of the sixth channel will be provided at the output of the last multiplexer 32. This will order the sixth channel which has priority over the third channel to be placed first so that the microprocessor means process this sixth channel before the third channel.

The order of priority of the channels allocated by this arrangement of the priority decoder may of course be modified. The channel priority during interruptions must lead to the channel with the highest priority being placed first in the correlation stage to be presented to the microprocessor means.

Of course, other embodiments of the radiofrequency signal receiver may also be envisaged within the knowledge of those skilled in the art without departing from the scope of the invention defined by the claims. For example, the radiofrequency signal receiver with the priority decoder could be used within the field of telephony insofar as it is necessary to arranged several correlation channels in said receiver.

What is claimed is:

1. A radiofrequency signal receiver including means for receiving and shaping said radiofrequency signals into intermediate signals, a correlation stage which includes several correlation channels for receiving the intermediate signals, microprocessor means connected to said correlation stage for the transfer of control and/or data signals, wherein it includes channel selection means connected to all the channels of the correlation stage and to the microprocessor means, said selection means allowing the channel with the highest priority among the operating channel or channels which have each transmitted an interruption signal for a data transfer from the selected channel to the microprocessor means, to be placed first in a virtual channel, in accordance with a defined order of priority for all the channels.

2. A receiver according to claim 1, wherein the selection means are a priority decoder wherein each correlation channel is represented by its identification number so as to define the order of priority as a function of this identification number, the channel having the highest priority being that whose determined identification number is the highest or the lowest among the operating channel or channels having each transmitted an interruption signal for a data transfer from the selected channel to the microprocessor means.

3. A receiver according to one of claims 1 and 2, wherein, after reading the data from the selected channel placed in the virtual channel, the microprocessor means transmit a read confirmation signal to said channel in order to cancel the interruption caused by this channel and to select the next channel with the highest priority which has transmitted an interruption signal.

4. A receiver according to claim 2, wherein the priority decoder includes a number of multiplexers placed one after the other corresponding to the number of channels to be controlled, for example 12 channels, the output of each multiplexer being connected to an input of a following multiplexer except for the output of the last multiplexer intended to select the channel with the highest priority, each multiplexer receiving at another input the identification number of a respective channel in a defined order, an interruption signal from each channel instructing the respective multiplexer to transmit at its output the identification number of the channel when an interruption signal from said channel is applied to said respective multiplexer.

5. A receiver according to claim 1, wherein each correlation channel includes a correlator receiving the intermediate signals, and a controller for implementing an algorithm for processing the digital signals in all the synchronisation tasks during the search and tracking of a determined satellite.

6. A receiver according to claim 2, wherein the correlation stage, the microprocessor means and the priority decoder are made on a same semiconductor substrate, for example made of silicon.
